(19) United States
(12) Patent Application Publication
(10) Pub. No.: US 2008/0075303 A1
(43) Pub. Date: Mar. 27, 2008

(54) Equalizer control method, medium and system in audio source player

(75) Inventors: Hyoung Gook Kim, Yongin-si (KR); Ki Wan Eom, Yongin-si (KR); Yuan Yuan She, Yongin-si (KR); Xuan Zhu, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 11/715,376

(22) Filed: Mar. 8, 2007

(30) Foreign Application Priority Data
Sep. 25, 2006 (KR) 10-2006-0092858

(51) Int. Cl. H03G 5/00

(52) U.S. Cl. 381/103

(57) ABSTRACT

An equalizer control system is provided. The equalizer control system includes a first sound mode identifier to identify a first sound mode for controlling the equalizer from a plurality of sound modes, by classifying an audio feature value, extracted from a sequential audio stream, into a category selected from a plurality of categories, the category corresponding to the first sound mode, a second sound mode identifier to identify a second sound mode for controlling the equalizer, from the plurality of sound modes, by segmenting a sound source into a music genre using a highlight extracted from stored music, and an equalizer controller to analyze the first sound mode and the second sound mode, select one of the first sound mode and the second sound mode, and control the equalizer according to the selected sound mode.

### CROSS-REFERENCE TO RELATED APPLICATIONS

This application claims the benefit of Korean Patent Application No. 10-2006-0092858, filed on Sep. 25, 2006, in the Korean Intellectual Property Office, the disclosure of which is incorporated herein by reference.

### BACKGROUND

1. Field

One or more embodiments of the present invention relate to an equalizer control method, medium and system that automatically control an equalizer of a digital multimedia player. More particularly, one or more embodiments of the present invention relates to the equalizer control method, medium and system that automatically controls the equalizer of the digital multimedia player and that can classify a genre of music, played in the digital multimedia player, and automatically control a sound mode of the equalizer according to a classified genre of music.

2. Description of the Related Art

An equalizer is an electronic filter that modifies the frequency response of a system for a specific purpose. In music and sound reproduction, equalizers can compensate for unwanted characteristics of the acoustic environment such as sound reflections or absorption, or can be used to customize the frequency output for a particular genre of music. Generally, a digital multimedia player may use an equalizer to enhance sound and thus may increase the enjoyment of a user listening to music, or other audio content. Such a digital multimedia player may include an MP3 player, a CD player, a car stereo, and an AM/FM/XM broadcast receiver, for example. More specifically, the equalizer controls a volume level of a specific audio frequency band. For example, when the user is listening to music and wants to listen only to, or emphasize, a particular instrument, the user may use the equalizer to selectively amplify a frequency band having the sound of the specific instrument. Conversely, when the user wants to selectively diminish the sound of a particular instrument, the user may selectively reduce the frequency band having the sound of the specific instrument.

Generally, the audible frequency band ranges from approximately 20 Hz to 20 kHz. A bass drum typically occupies a band of from approximately 30 Hz to 90 Hz, while a vocal range, e.g. a bass, a baritone, a tenor, an alto and a soprano, occupies a band of from approximately 80 Hz to 3 kHz, various instruments, e.g., a violin, a piano, a guitar, a piccolo, a flute, a trumpet, a tenor saxophone, an electronic organ, occupy a band of from approximately 27.5 Hz to 4.3 kHz, while other instruments, e.g., the piccolo and cymbals, occupy a band from approximately 4 kHz to 20 kHz.

A conventional equalizer control technique, will be discussed below.

As an example, when the user thinks a percussions drum's sound is comparatively lower than the sound of other instruments, the user may make the drum sound louder by using an equalizer to boost the principal frequency from 20 Hz to 80 kHz.

Conversely, when the user thinks the sound of cymbals are comparatively louder than the sound of other instruments, the user may make the cymbals' sound lower by using an equalizer to lower the principal main frequency band occupied by the cymbals, from 4 Hz to 20 kHz.

Accordingly, the user may listen to music in a preferred way by manually controlling each frequency band of the equalizer. However, the problem with manual control of an equalizer is that the user may be required to control the equalizer manually for each and every song. Thus, the user may not fully use the equalizer, even though the digital media player is equipped with the equalizer, due to the inconvenience of constantly having to adjust the output levels by hand. In fact, the user may avoid adjusting the equalizer at all, simply to avoid the inconvenience of having to readjust the levels for each and every song.

In a conventional equalization technique, as an example, each music file is encoded with a sub-code by a music supplier. The equalizer may be automatically controlled using a music genre, predetermined according to the particular song or music file.

In another example of a conventional equalization technique, an equalizer mode is manually controlled by the user via a user interface in the audio player. Alternatively, the equalizer mode, may be automatically selected using tag information of the encoded music file.

In another example of a conventional equalization technique, the equalizer is controlled using program information provided in a digital radio broadcast.

However, conventional equalizer control methods may not automatically perform equalization when the predetermined music genre information, the file tag information, or the program information, are not included in the music file. Accordingly, an equalizer control method, medium and system that can automatically control an equalizer for a digital multimedia player, classify a genre of music played in the digital multimedia player, and automatically control a sound mode of the equalizer according to a classified genre, has been found desirable by the inventors.

### SUMMARY

An embodiment of the present invention provides an equalizer control method, medium and system which classifies a sequential audio stream into a music genre by analyzing a music signal, played in a sound source player, recognizes a sound mode according to the classified music genre, and automatically controls an equalizer according to the recognized sound mode.

An embodiment of the present invention also provides an equalizer control method, medium and system which variously establishes a frequency band of each instrument depending upon each music genre by considering that the frequency band of the instrument differs depending upon the each music genre, stored in a sound source player.

An embodiment of the present invention also provides an equalizer control method, medium and system which detects a highlight of music stored in a sound source player, extracts an audio feature value from the detected highlight, classifies a sequential audio stream into a music genre using the extracted audio feature value, and automatically controls an equalizer according to the classified music genre.

An embodiment of the present invention also provides an equalizer control method, medium and system which classifies a sequential audio stream into a music genre by analyzing a played sound source or a stored sound source, recognizes a sound mode according to the classified music genre, and automatically controls an equalizer according to the recognized sound mode.

Additional aspects and/or advantages of the invention will be set forth in part in the description which follows and, in part, will be apparent from the description, or may be learned by practice of the invention.

To achieve at least the above and/or other aspects and advantage, embodiments of the present invention include an equalizer control system including a first sound mode identifier to identify a first sound mode for controlling the equalizer from a plurality of sound modes, by classifying an audio feature value, extracted from a sequential audio stream, into a category selected from a plurality of categories, the category corresponding to the first sound mode, a second sound mode identifier to identify a second sound mode for controlling the equalizer, from the plurality of sound modes, by segmenting a sound source into a music genre using a highlight extracted from stored music, and an equalizer controller to analyze the first sound mode and the second sound mode, select one of the first sound mode and the second sound mode, and control the equalizer according to the selected sound mode.

To achieve at least the above and/or other aspects and advantage, embodiments of the present invention include an equalizer control method in a sound player including classifying a sequential audio stream into one of a category of music and non-music, using an extracted audio feature value, classifying the music classified sequential audio stream into a music genre, identifying a sound mode from a plurality of sound modes according to the classified music genre, and controlling the equalizer corresponding to the identified sound mode.

To achieve at least the above and/or other aspects and advantage, embodiments of the present invention include an equalizer control method in a sound player including extracting a highlight from a stored music clip, classifying the music clip into a music genre using the extracted highlight, identifying a sound mode from a plurality of sound modes, according to the classified music genre of the music clip, and controlling the equalizer corresponding to the identified sound mode.

To achieve at least the above and/or other aspects and advantage, embodiments of the present invention include an equalizer control method in a sound player including classifying a sequential audio stream into one of a category of music and non-music, based on an extracted audio feature value, identifying a first sound mode of the equalizer from a plurality of sound modes, according to the classified category, identifying a second sound mode of the equalizer from the plurality of sound modes, by classifying stored music into a music genre using a highlight extracted from the stored music, establishing in advance an equalizer mode, corresponding to each of the sound modes, selecting one of the first sound mode and the second sound mode by analyzing the first and second sound modes, and controlling the equalizer according to the selected sound mode.

To achieve at least the above and/or other aspects and advantage, embodiments of the present invention include at least one medium comprising computer readable code to control at least one processing element to implement a summary clip generation method including classifying a sequential audio stream into a one of a category of music and non-music based on an extracted audio feature value, classifying the music classified sequential audio stream into a music genre, identifying a sound mode from a plurality of sound modes according to the classified genre, and controlling the equalizer, corresponding to the identified sound mode.

To achieve at least the above and/or other aspects and advantage, embodiments of the present invention include an equalizer control method including extracting an audio feature from audio data, classifying the audio data into a music genre based on the extracted audio data, and controlling the equalizer to determine a sound mode, from a plurality of sound modes, based on the classified music genre.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates an equalizer control system according to an embodiment of the present invention;

FIG. 2 illustrates an equalizer control method according to an embodiment of the present invention;

FIG. 3 illustrates an equalizer control method according to an embodiment of the present invention;

FIG. 4 illustrates feature extractors extracting an audio feature value according to an embodiment of the present invention;

FIG. 5 illustrates music or non-music classifiers according to an embodiment of the present invention;

FIG. 6 illustrates a music genre classifier according to an embodiment of the present invention; and

FIG. 7 illustrates a frequency response of a sound mode according to an embodiment of the present invention.

### DETAILED DESCRIPTION OF EMBODIMENTS

Reference will now be made in detail to one or more embodiments of the present invention, examples of which are illustrated in the accompanying drawings, wherein like reference numerals refer to the like elements throughout. One or more embodiments are described below to explain the present invention by referring to the figures.

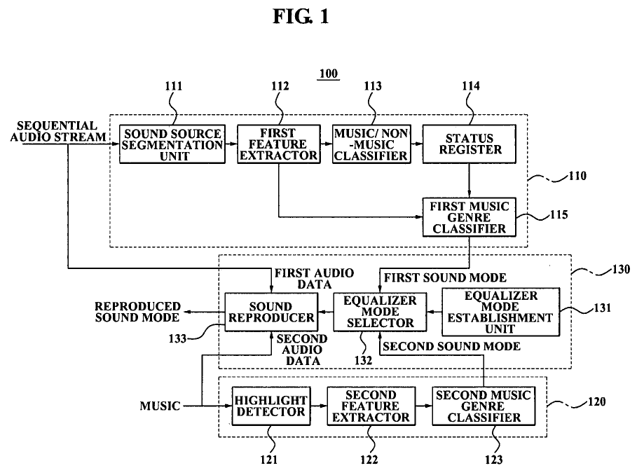

FIG. 1 illustrates an equalizer control system 100 according to an embodiment of the present invention.

Referring to FIG. 1, the equalizer control system 100 may include a first sound mode recognizer 110, a second sound mode recognizer 120, and an equalizer controller 130, for example.

The first sound mode recognizer 110 classifies a sequential audio stream into a category using an extracted audio feature value, and recognizes a first sound mode for controlling the equalizer according to the classified category. The first sound mode recognizer 110 may include a sound source segmentation unit 111, a first feature extractor 112, a music or non-music classifier 113, a status register 114, and a first music genre classifier 115, for example.

The sound source segmentation unit 111 receives a sequential audio stream from a sound source provider such as an MP3 player, a CD player, a radio receiver, a television, a car stereo, or other audio device, and segments the audio stream into an audio clip of a predetermined time interval. Specifically, the sound source segmentation unit 111 may segment the audio stream into five audio clips, each of six seconds, without overlapping the audio stream when the sequential audio stream is 30 seconds in length, as an example.

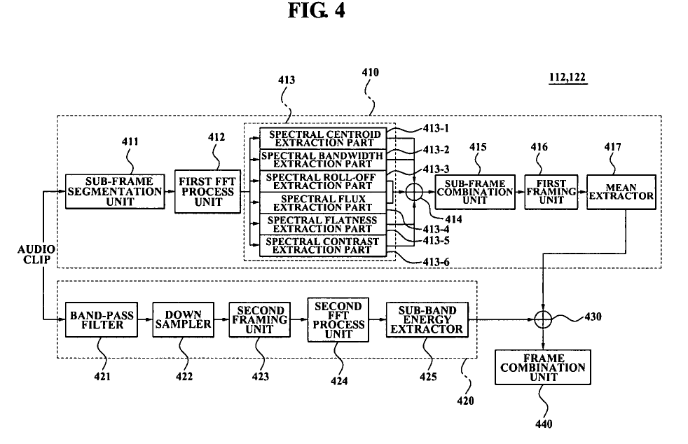

In an embodiment, the first feature extractor 112 extracts an audio feature value from the audio clip, which will be described in more detail by referring to FIG. 4.

FIG. 4 illustrates feature extractors 112 and 122, such as of FIG. 1, extracting an audio feature value.

Referring to FIG. 4, the feature extractors 112 and 122 may extract the audio feature value, e.g. a timbre feature value and a rhythm feature value, and may include a timbre feature extractor 410, a rhythm feature extractor 420, a second adding calculation unit 430 and a frame combination unit 440, for example.

The timbre feature extractor 410 may extract the timbre feature from an audio clip, and may include a sub-frame segmentation unit 411, a first fast Fourier transform (FFT) process unit 412, a spectral feature extractor 413, an adding calculation unit 414, a sub-frame combination unit 415, a first framing unit 416, and an mean extractor 417, for example. In an embodiment, the sub-frame segmentation unit 411 may segment the audio clip into sub-frames each with a length of approximately 20 ms, and may analyze each of the sub-frame lengths using a sub-frame step of approximately 10 ms. The first FFT process unit 412 may perform a short term FFT with respect the segmented audio clip of approximately 20 ms, and may convert the FFT transformed audio clip to a frequency band. The spectral feature extractor 413 may segment each of the sub-frames of 65 Hz to 837 Hz into a seven octave frequency band, as an example, and may extract spectral features of the audio clip, for example, a spectral centroid, a spectral bandwidth, a spectrum roll-off, a spectral flux, a spectral flatness, and the like, using Equations 1 through 8 below.

The spectral feature extractor 413 may include a spectral centroid extraction part 413-1, a spectral bandwidth extraction part 413-2, a spectrum roll-off extraction part 413-3, a spectral flux extraction part 413-4, a spectral flatness extraction part 413-5 and a spectral contrast extraction part 413-6, for example.

The spectral centroid extraction part 413-1 extracts the spectral centroid of the audio clip using Equation 1, below, as an example, in a seven octave frequency band.

$$\begin{matrix}\text{Equation} 1 \text{:} & \\ {C}_{t} = {\sum }_{i = {N}_{0}}^{N} ( {\vert {S}_{it} ( i ) \vert}^{2} \times i ) / {\sum }_{i = {N}_{0}}^{N} {\vert {S}_{t} ( i ) \vert}^{2} & \end{matrix}$$

In this instance, Sₜ(i) indicates a frequency spectrum.

The spectral bandwidth extraction part 413-2 may extract a spectral bandwidth of the audio clip using Equation 2, below, as an example, in a seven octave frequency band.

$$\begin{matrix}\text{Equation} 2 \text{:} & \\ {B}_{t} = \sqrt{{\sum }_{i = {N}_{0}}^{N} ( {\vert {S}_{t} ( i ) \vert}^{2} \times {( i - {C}_{t} )}^{2} ) / {\sum }_{i = {N}_{0}}^{N} {\vert {S}_{t} ( i ) \vert}^{2}} & \end{matrix}$$

The spectrum roll-off extraction part 413-3 may extract the spectral roll-off of the audio clip using Equation 3, below, as an example, in a seven octave frequency band.

$$\begin{matrix}\text{Equation} 3 \text{:} & \\ {\sum }_{i = {N}_{0}}^{Rt} {\vert {S}_{t} ( i ) \vert}^{2} = 0.95 \times {\sum }_{i = {N}_{0}}^{N} {\vert {S}_{t} ( i ) \vert}^{2} & \end{matrix}$$

The spectral flux extraction part 413-4 may extract the spectral flux of the audio clip using Equation 4, below, as an example, in a seven octave frequency band.

$$\begin{matrix}\text{Equation} 4 \text{:} & \\ {F}_{t} = {\sum }_{i = {N}_{0}}^{N} {( \vert {S}_{t} ( i ) \vert + \vert {S}_{t - 1} ( i ) \vert )}^{2} & \end{matrix}$$

The spectral flatness extraction part 413-5 may extract the spectral flatness of the audio clip using Equation 5, below, as an example, in a seven octave frequency band.

$$\begin{matrix}\text{Equation} 5 \text{:} & \\ {L}_{t} = 10 \times log ( \sqrt[( N - {N}_{0} + 1 )]{{\prod }_{i = {N}_{0}}^{N} {\vert {S}_{t} ( i ) \vert}^{2}} / ( ( {\sum }_{i = {N}_{0}}^{N} {\vert {S}_{t} ( i ) \vert}^{2} ) / ( N - {N}_{0} + 1 ) ) ) & \end{matrix}$$

The spectral contrast extraction part 413-6, may extract a spectral contrast feature set of the audio clip using Equations 6 through 8, below, as an example, in a seven octave frequency band. In this instance, the spectral contrast feature set may include a peak, a valley, and a mean log-energy with respect to seven octave scale sub-bands, for example.

$$\begin{matrix}\text{Equation} 6 \text{:} & \\ {P}_{t} ( k ) = log ( \frac{1}{α {N}_{k}} {\sum }_{i = 1}^{α {N}_{k}} {\vert {S}_{t} ( k , i ) \vert}^{2} ) & \end{matrix}$$

Equation 6 may indicate the peak log-energy with respect to the seven octave-scale sub-bands.

$$\begin{matrix}\text{Equation} 7 \text{:} & \\ {V}_{t} ( k ) = log ( \frac{1}{α {N}_{k}} {\sum }_{i = 1}^{α {N}_{k}} {\vert {S}_{t} ( k , {N}_{k} - i + 1 ) \vert}^{2} ) & \end{matrix}$$

Equation 7 may indicate the valley log-energy with respect to the seven octave-scale sub-bands.

$$\begin{matrix}\text{Equation} 8 \text{:} & \\ {M}_{t} ( k ) = log ( \frac{1}{{N}_{k}} {\sum }_{i = 1}^{{N}_{k}} {\vert {S}_{t} ( k , i ) \vert}^{2} ) & \end{matrix}$$

Equation 8 may indicate the mean log-energy with respect to the seven octave-scale sub-bands.

The first adding calculation unit 414 may add a spectral feature vector, respectively extracted from the spectral centroid extraction part 413-1, the spectral bandwidth extraction part 413-2, the spectrum roll-off extraction part 413-3, the spectral flux extraction part 413-4, the spectral flatness extraction part 413-5 and the spectral contrast extraction part 413-6, as an example. In total, in one embodiment, a 26-dimensional timbre feature value may be extracted.

In an embodiment the sub-frame combination unit 415 combines sub-frames of the segmented spectral feature vector, the first framing unit 416 frames the combined sub-frames, and the mean extractor 417 may extract a 52-dimensional audio feature value by extracting a mean and a variance of the sub-frame using a frame length of three seconds and a frame step of 0.25 seconds, for example, although other frame lengths and frame steps may be used.

The rhythm extractor 420 extracts the rhythm feature from the audio clip and may include a band-pass filter 421, a down sampler 422, a second framing unit 423, a second FFT process unit 424, and a sub-band energy extractor 425, for example. Rhythm energy generated by an instrument is generally distributed in a sub-band made up of lower energy frequencies. Accordingly, the band-pass filter 421 filters so as to pass a bandwidth frequency of such a lower frequency sub-band from the audio clip in order to extract a rhythm of a music signal. As an example, the band-pass filter 421 may extract an audio signal, corresponding to bands of from approximately 65 Hz to 131 Hz from the audio clip, using a matched band-pass filter. The audio signal corresponds to a frequency band of a first of seven octaves, as an example. The down sampling unit 422 may down-sample the filtered audio signal using a sampling rate of approximately 200 Hz, for example. The second framing unit 423 frames the down-sampled audio signal. The second FFT process unit 424 performs the FFT with respect to the down-sampled audio signal using a frame length of three seconds and a frame step of 0.25 seconds, although other frame lengths and frame steps may be used, and converts the FFT transformed audio signal to a frequency band. The sub-band energy extractor 425 may extract a 12-dimensional rhythm feature value for each of the frames by extracting the sub-band energy from each of the filters using 12 triangular filters in which a power spectrum is logarithmically distributed, for example. The second adding unit 430 may add the timbre feature value, extracted from the timbre feature extraction unit 410, to the rhythm feature value, extracted from the rhythm feature extraction unit 420. The frame combination unit 440, may further combine the feature vector, including the timbre feature value and the rhythm feature value, into one frame. In an embodiment, the frame combination unit 440 may acquire a 64-dimensional audio feature in total by combining the 52-dimensional feature value, extracted as the timbre feature value, with the 12-dimensional audio feature value, extracted as the rhythm feature value.

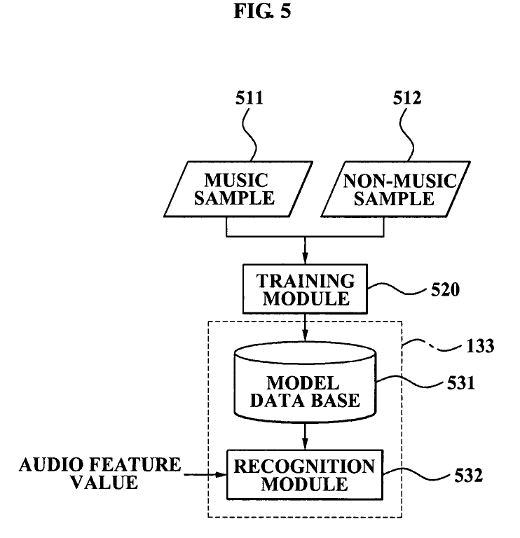

The music or non-music classifier 113 may classify the audio clip into music or non-music using the audio feature value, for example. Hereinafter, a configuration and operation of the music or non-music classifier 113 will be described in more detail by referring to FIG. 5.

FIG. 5 illustrates music or non-music classifiers 113 according to an embodiment of the present invention.

Referring to FIG. 5, the music or non-music classifiers 113 may include a model database 531 and a recognition module 532, for example. A training module 520 respectively forms a music model and a non-music model by training to distinguish music from non-music using a music sample 511 and a non-music sample 512. The music sample 511 may include samples of a variety of music types including, for example, classical music, pop music, jazz music, dance music, and rock music. Any of the foregoing music types may benefit from equalizer control because there is a response difference according to frequency. The non-music sample 512 may include samples of a variety of non-musical content including, for example, news, an announcement, a poem recital, an audio book and talk radio content. The non-musical content generally does not require equalizer control because there is no response difference according to frequency. The model database 531 may maintain the music model and the non-music model according to the training result. The recognition module 532 may search for the music model or the non-music model, corresponding to the audio feature value, by referring to the model database 531, and may classify the audio clip into music or non-music according to the retrieved result. The recognition module 532 may, thus, determine whether either the music model or the non-music model, correspond to an audio feature value, by referring to the model database 531, and classifies the audio clip into the music or the non-music according to the determined result. By referring to the model database 531, the recognition module 532 classifies the audio clip as music when the audio feature value is similar to the music model. Also, by referring to the model database 531, the recognition module 532 classifies the audio clip as non-music when the audio feature value is similar to the non-music model.

The status register 114 records a category status of the classified sound source. Namely, the status register 114 may record the category of the classified sound source as music, or non-music depending on the determination made by the recognition module 532. In an embodiment the status register 114 retains the previously registered category information whenever a category of the presently classified sound source is identical to the category of a previously classified sound source. Namely, if the previously classified sound source is music, and the presently classified sound source is again music, the status register 114 may maintain the existing registered category information. Conversely, when the category of the previously classified sound source is music, when the category of the previously classified sound source is non-music, the status register 114 changes the registered category information. As an example, the status register 114 may record ‘1’ when the category information of the sound source is the music, and the status register 114 may record ‘0’ when the category information of the sound source is the non-music. Conversely, the status register 114 may reverse the registered category information of ‘0’ into ‘1’ when the category information of the present sound source is music, and when the category information of the previously registered sound source is non-music.

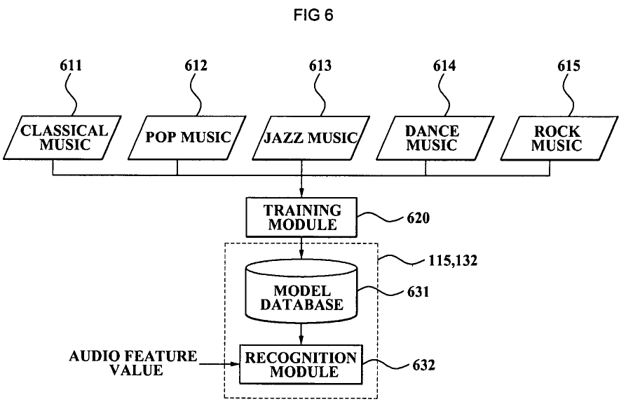

The first music genre classifier 115 may classify a music genre of the music according to an extracted audio feature when the category information of the sound source, registered in the status register 114, is music, and provide a first sound mode to the equalizer controller 130. Hereinafter, an operation of the first music genre classifier will be described in more detail by referring to FIG. 6.

FIG. 6 illustrates a music genre classifier according to an embodiment of the present invention.

Referring to FIG. 6, the music genre classifiers 115 and 123 may include a model database 631 and a recognition model 632, for example. The music genre classifiers 115 and 123 may apply statistical classification techniques, for example, a Gaussian Classifier (GS), a Gaussian Mixture Model (GMM), a K-Nearest Neighbor (KNN), a Support Vector Machine (SVM), and the like, noting that alternate techniques are equally available.

The music genre may include classical music 611, pop music 612, jazz music 613, dance music 614, rock music 615, or any other music genre. The training module 620 forms a model that corresponds to each music genre through training, using samples of the music genres, and records the formed music genre model in the model database 631. The model database 631 may record and store a model for each music genre. The recognition model 632 may search for the music genre model, corresponding to the audio feature value, by referring to the model database 631, and may classify the music genre according to the retrieved result. Namely, the recognition module 632 may classify the music genre as classical music 611 when the audio feature value corresponds to the classical music genre model of the model database 631. Alternatively, the recognition module 632 may classify the music genre as pop music 612 when the audio feature value corresponds to the classical music genre model of the model database 631. Similarly, the recognition module 632 may classify the music genre as jazz music 613, dance music 614, rock music 615, or any other music genre.

As an example, the music genre classifier 115 may provide the equalizer controller 103 with the first sound mode. Further, the music genre classifier 115 may maintain the present sound mode of the equalizer when the present category status is identical to a previous category status, after comparing the present category status with the previous category status.

As another example, the music genre classifier 115 may provide the equalizer controller 130 with the first sound mode, maintaining the present sound mode without a change from the previous mode, when there is no change in a present audio clip status from one music section to another music section.

As still another example, the music genre classifier 115 may provide the equalizer controller 130 with the first sound mode, maintaining the equalizer as a flat mode when there is no change in a present audio clip status from one non-music section to another non-music section.

As yet another example, the music genre classifier 115 may classify the music genre of the present audio clip when there is a change in the present audio clip status from a non-music section to a music section, and provide the equalizer controller 130 with the first sound mode according to the classified music genre information.

The second sound mode recognizer 120 classifies each music clip into a music genre using a highlight extracted from stored music, and recognizes a second sound mode according to the classified music genre. Specifically, the second sound mode recognizer 120 may classify each music into a music genre using a highlight extracted from the music, stored in an MP3 player, a CD player, and the like, and may recognize the second sound mode to control the equalizer according to the classified music genre. The second sound mode recognizer 120 may include a highlight detector 121, a second feature extractor 122, and a second music genre classifier 123, for example.

In an embodiment the highlight detector 121 detects a highlight, representing a clip of music, within a predetermined time. Specifically, the highlight detector 121 may detect the highlight to reduce the large amount of time that would be required to determine the entire stored music clip. As an example, the highlight detector 121 may calculate a mean energy from six seconds of a music signal, extract a maximum mean energy from the six second segment of the music signal, and subsequently detect the music highlight. The processing time required for this method is less than the processing time needed for a method detecting a repeated section using an audio fingerprint similarity matrix, for example.

The second feature extractor 122 extracts an audio feature, having a value less than a reference value, in a section, and an audio feature, having a value greater than a reference value, in a section, from the highlight. Specifically, the second feature extractor 122 may extract the audio feature value, e.g., a timbre feature value and a rhythm feature value, by analyzing the highlight. The audio feature having a value less than a reference value in the section may correspond to the timbre feature value, and the audio feature having a value greater than a reference value in the section may correspond to the rhythm feature value, for example.

The second music genre classifier 123 classifies the music into the music genre using the audio feature value, and provides the equalizer controller 130 with the second sound mode.

The equalizer controller 130 selects a sound mode for controlling the equalizer by analyzing the first sound mode and the second sound mode, and controls the equalizer according to the selected sound mode. The equalizer controller 130 may include an equalizer mode establishment unit 131, an equalizer mode selector 132, and a sound reproducer 133, for example.

The equalizer mode establishment unit 131 establishes in advance a frequency response of an equalizer corresponding to the first sound mode or the second sound mode. Specifically, the equalizer mode establishment unit 131 may establish in advance an equalizer mode whereby a magnitude of a sound source at each frequency bandwidth is controlled according the first sound mode or the second sound mode.

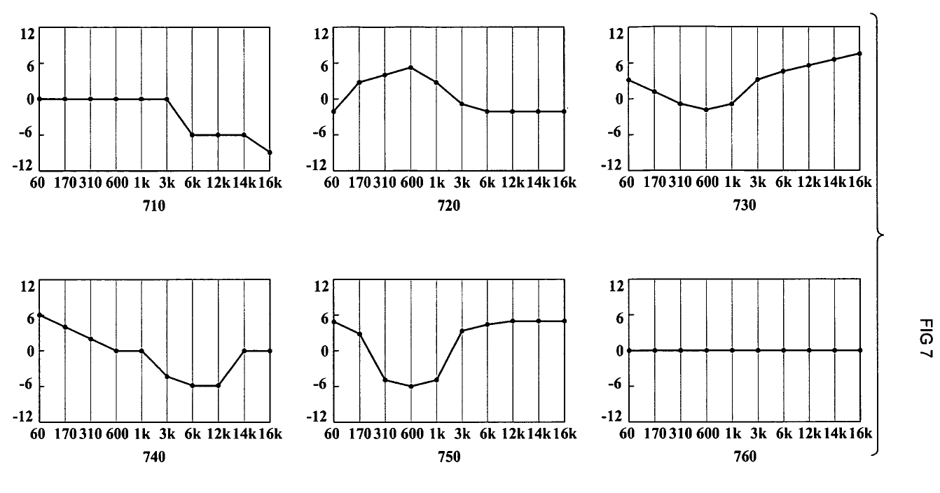

FIG. 7 illustrates a frequency response of a sound mode according to an embodiment of the present invention.

Referring to FIG. 7, the illustrated graph 710 indicates that when the sound mode is a classical music mode, a response of the equalizer is constant from 60 Hz to 3 kHz, the response of the equalizer decreases from 3 kHz to 6 kHz, the response of the equalizer is constant from 6 kHz to 14 kHz, and the response of the equalizer decreases from 14 kHz to 16 kHz, for example.

The illustrated graph 720 indicates that when the sound mode is a pop music mode, the response of the equalizer increases from 60 Hz to 600 Hz, decreases from 600 Hz to 6 kHz, and is constant from 6 kHz to 16 kHz, for example.

The illustrated graph 730 indicates that when the sound mode is a jazz music mode, the response of the equalizer decreases 60 Hz to 600 Hz, and increases from 600 Hz to 16 kHz, for example.

The illustrated graph 740 indicates that when the sound mode is a dance music mode, the response of the equalizer decreases from 60 Hz to 12 kHz, increases in a frequency range of from 12 kHz to 14 kHz, and is constant from 14 kHz to 16 kHz, for example.

The illustrated graph 750 indicates that when the sound mode is a rock music mode, the response of the equalizer decreases from 60 Hz to 600 Hz, increases from 600 Hz to 12 kHz, and is constant from 12 kHz to 16 kHz, for example.

The illustrated graph 760 indicates that when the sound mode is a flat mode, the response of the equalizer is identical in all frequency ranges, for example.

The equalizer mode selector 132 may select an equalizer mode, corresponding to a sound mode selected from the first sound mode or the second sound mode, for example. Specifically, the equalizer mode selector 132 selects the equalizer mode according to the first sound mode when a sound source, presently provided from the equalizer control system 100, is sequential audio data, and selects the equalizer mode according to the second sound mode when playing the stored sound source.

The equalizer mode selector 132 may select the equalizer mode having the classical music frequency response of graph 710 when the music genre, classified according to the first sound mode or the second sound mode, is classical music 611.

The equalizer mode selector 132 may select the equalizer mode having the pop music frequency response of graph 720 when the music genre, classified according to the first sound mode or the second sound mode, is pop music 612.

The equalizer mode selector 132 may select the equalizer mode having the jazz music frequency response of graph 730 when the music genre, classified according to the first sound mode or the second sound mode, is jazz music 613.

The equalizer mode selector 132 may select the equalizer mode having the dance music frequency response of graph 740 when the music genre, classified according to the first sound mode or the second sound mode, is dance music 614.

The equalizer mode selector 132 may select the equalizer mode having the rock music frequency response of graph 750 when the music genre, classified according to the first sound mode or the second sound mode, is rock music 615.

The equalizer mode selector 132 may select the equalizer mode having the flat mode frequency response of graph 760 when the music genre, classified according to the first sound mode or the second sound mode, is non-music. Any other category of music may be similarly classified and a corresponding equalizer mode having a pre-determined frequency response, may be selected by the equalizer mode selector 132.

The sound reproducer 133 reproduces sound according to the frequency response of the selected equalizer mode. Specifically, the sound reproducer 133 may reproduce sound from the first audio data or the second audio data so that the established frequency response is stressed according to the selected equalizer mode.

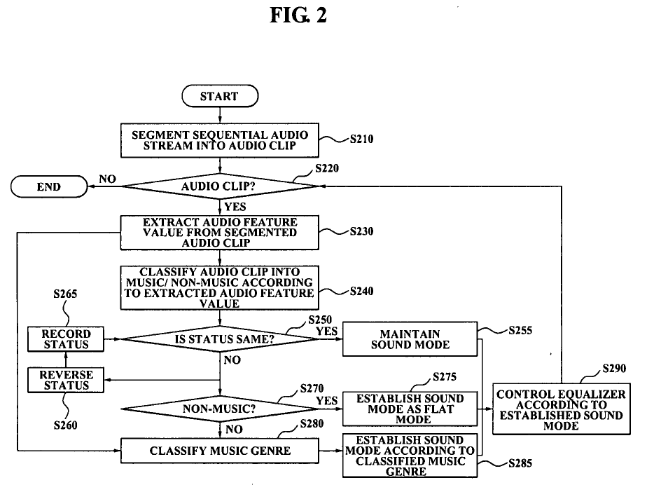

FIG. 2 illustrates an equalizer control method according to an embodiment of the present invention. Although some operations of the equalizer control method are discussed with respect to the equalizer control system 100 of FIG. 1, the method is independent of the system 100 and may be performed by a variety of equalizer control systems.

Referring to FIG. 2, in operation S210, a sequential audio stream is segmented into an audio clip having a predetermined time interval.

In operation S220, it may be determined whether inputted audio data is the audio clip, e.g., by the equalizer control system 100 of FIG. 1.

When the inputted audio data is the audio clip, an audio feature value may be extracted from the segmented audio clip, e.g., by the equalizer control system 100, in operation S230. Specifically, an audio feature may be extracted having a value less than a reference value, in a section, and an audio feature may be extracted having a value greater than a reference value, in a section, from the audio clip, e.g. by the equalizer control system 100, in operation S230. Specifically, a timbre feature may be extracted for the audio feature having a value less than the reference value, and a rhythm feature may be extracted for the audio feature having a value greater than the reference value, e.g. by the equalizer control system 100.

In operation S240, the audio clip may be classified into categories such as music or non-music, e.g., by the equalizer control system 100.

In operation S240, an extracted audio feature value may be compared with a music model or a non-music model or both, e.g., by the equalizer control system 100. The audio clip may be classified into a music category when the audio feature value is similar to a music model, and may be classified into a non-music category when the audio feature value is similar to a non-music model.

In operation S250, it may be determined whether the presently classified category status is identical to a previously classified category status, e.g., by the equalizer control system 100.

A previous sound mode may be maintained as a present sound mode in operation S255 when the presently classified category status is identical to the previously classified category status, e.g., by the equalizer control system 100.

A previously registered category status may be reversed in operation S260 when the presently classified category status is not identical to the previously classified category status, and the reversed category may be recorded, for example, in the status register 114 of FIG. 1, e.g., by the equalizer control system 100, in operation S265.

In operation S270, it may be determined whether the audio clip is non-music, e.g., by the equalizer control system 100.

In operation S275, it may be established whether the sound mode as a flat mode when the audio clip is non-music, e.g., by the equalizer control system 100.

When the audio clip is music, the music genre of the music may be classified using the extracted audio feature value, e.g., by the equalizer control system 100, in operation S280.

In operation S285, the sound mode may be established according to the classified music genre, e.g., by the equalizer control system 100.

In operation S290, an equalizer may be controlled according to the established sound mode, e.g., by the equalizer control system 100.

As described above, an equalizer control method according to an embodiment of the present invention classifies an audio clip into a category of music or non-music using an extracted audio feature value, classifies a music genre of the music using the extracted audio feature value when the audio clip is music based on the classified music category, establishes in advance an equalizer mode corresponding to each of the music genres, and controls an equalizer according to the established equalizer mode.

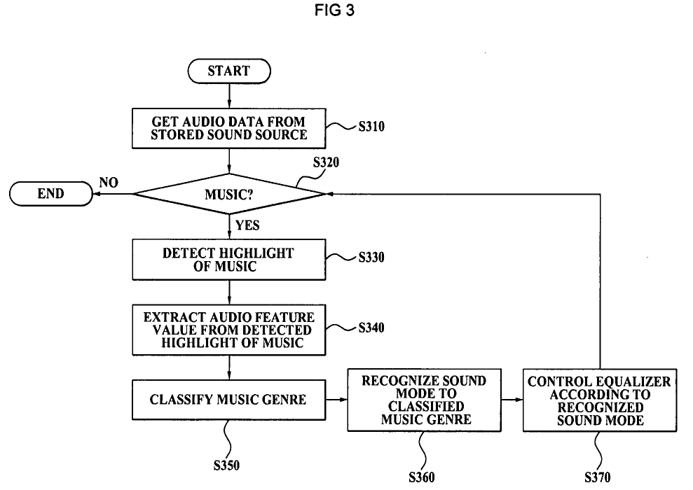

FIG. 3 illustrates an equalizer control method according to another embodiment of the present invention.

Referring to FIG. 3, one clip of audio data may be retrieved from stored sound sources, e.g., by the equalizer control system 100, in operation S310, for example. Specifically, the data may be extracted from a plurality of sound sources stored in an MP3 player, a CD player, or any audio data output device.

In operation S320, it may be determined whether the audio data is music, e.g., by the equalizer control system 100.

When the audio data is music, a highlight of the music may be detected, e.g., by the equalizer control system 100, in operation S330.

In operation S340, an audio feature value may be extracted from the detected music highlight, e.g., by the equalizer control system 100. The audio feature value may include a timbre feature value and a rhythm feature value, for example. Specifically, an audio feature may be extracted having a value less than a reference value in a section, and an audio feature may be extracted having a value greater than a reference value in a section, from the music highlight, e.g., by the equalizer control system 100, in the operation S340.

In operation S350, a music genre of the music may be classified using the extracted audio feature, e.g., by the equalizer control system 100. Specifically, a music genre model may be detected that is similar to the extracted audio feature value, and the music genre may be classified according to the detected music genre model, formed by training, e.g., by the equalizer control system 100.

In operation S360, a sound mode may be recognized according to the classified music genre, e.g., by the equalizer control system 100.

In operation S370, an equalizer may be controlled according to the recognized sound mode, e.g., by the equalizer control system 100. Specifically, in operation S370, a frequency response may be provided corresponding to the established sound mode, the frequency response selected for the recognized sound mode, and the sound reproduced by controlling the equalizer according to the selected frequency response, for example.

As described above, an embodiment of the present invention may extract a highlight from stored music, classify the music genre of the music using the extracted highlight, recognize a sound mode according to the classified music genre, establish in advance an equalizer mode corresponding to each of the sound modes, and control the equalizer according to the equalizer mode establishment.

Another embodiment of the present invention may classify a category of music or non-music using the audio feature value, extracted from the sequential audio stream, recognize the first sound mode of the equalizer according to the classified category, recognize the first sound mode of the equalizer by classifying the music genre using the highlight extracted from the stored music, establish in advance the equalizer mode corresponding to each of the sound modes, select one sound mode by analyzing the first or second sound modes, and control the equalizer according to the equalizer mode, corresponding to the selected sound mode.

In addition to this discussion, one or more embodiments of the present invention may also be implemented through computer readable code/instructions in/on a medium, e.g., a computer readable medium, to control at least one processing element to implement any above described embodiment. The medium can correspond to any medium/media permitting the storing and/or transmission of the computer readable code.

The computer readable code can be recorded/transferred on a medium in a variety of ways, with examples of the medium including magnetic storage media (e.g., ROM, floppy disks, hard disks, etc.), optical recording media (e.g., CD-ROMs, or DVDs), and storage/transmission media such as carrier waves, as well as through the Internet, for example. Here, the medium may further be a signal, such as a resultant signal or bitstream, according to one or more embodiments of the present invention. The media may also be a distributed network, so that the computer readable code is stored/transferred and executed in a distributed fashion. Still further, as only a example, the processing element could include a processor or a computer processor, and processing elements may be distributed and/or included in a single device.

According to one or more embodiments of the present invention, there is provided an equalizer control method and a system using a method which classifies a sequential audio stream into a music genre by analyzing a music signal, played in a sound source player, recognizes a sound mode according to the classified music genre, and automatically controls an equalizer according to the recognized sound mode.

Also, according to one or more embodiments of the present invention, there is provided an equalizer control method and a system using the method which variously establishes a frequency band of each instrument depending upon each music genre by considering that the frequency band of the instrument differs depending upon the each music genre, stored in a sound source player.

Also, according to one or more embodiments of the present invention, there is provided an equalizer control method and a system using the method which detects a highlight of music stored in a sound source player, extracts an audio feature value from the detected highlight, classifies a sequential audio stream into a music genre using the extracted audio feature value, and automatically controls an equalizer according to the classified music genre.

Also, according to one or more embodiments of the present invention, there is provided an equalizer control method and a system using the method which classifies a sequential audio stream into a music genre by analyzing a played sound source or a stored sound source, recognizes a sound mode according to the classified music genre, and automatically controls an equalizer according to the recognized sound mode.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An equalizer control system comprising:
a first sound mode identifier to identify a first sound mode for controlling the equalizer from a plurality of sound modes, by classifying an audio feature value, extracted from a sequential audio stream, into a category selected from a plurality of categories, the category corresponding to the first sound mode;
a second sound mode identifier to identify a second sound mode for controlling the equalizer, from the plurality of sound modes, by segmenting a sound source into a music genre using a highlight extracted from stored music; and
an equalizer controller to analyze the first sound mode and the second sound mode, select one of the first sound mode and the second sound mode, and control the equalizer according to the selected sound mode.

2. The equalizer control system of claim 1, wherein the first sound mode identifier comprises:
a segmentation unit to segment the sequential audio stream into an audio clip of a predetermined time interval;
a feature extractor to extract an audio feature value from the audio clip;
a music/non-music classifier to classify the audio clip into one of music and non-music using the audio feature value;
a status register to record a category status of the sound source based on the category of the classified audio feature; and
a music genre classifier to classify the sequential audio stream into the music genre, according to the extracted audio feature, when the sound source is music.

3. The equalizer control system of claim 2, wherein the feature extractor extracts a timbre feature value and a rhythm feature value from the audio clip.

4. The equalizer control system of claim 2, wherein the music/non-music classifier classifies a present audio clip into one of the music and the non-music using the audio feature value.

5. The equalizer control system of claim 2, wherein the music genre classifier provides the equalizer controller with information of the first sound mode, maintaining a present sound mode of the equalizer, when a present category status is identical to a previous category status after comparing the present category status with the previous category status.

6. The equalizer control system of claim 5, wherein the music genre classifier provides the equalizer controller with information of the first sound mode, and maintains the present sound mode, without a change from the previous mode, when there is no change in a present audio clip status from one music section to another music section.

7. The equalizer control system of claim 5, wherein the music genre classifier provides the equalizer controller with information of the first sound mode, and maintains a sound mode of the equalizer controller as a flat mode, when the category of the present audio clip status does not change from a non-music section.

8. The equalizer control system of claim 2, wherein the status register records a reverse status of a previously recorded status when a present audio clip status is not identical to a previous audio clip status.

9. The equalizer control system of claim 8, wherein the music genre classifier classifies music into the music genre when there is a change from a non-music section to a music section, and provides the equalizer controller with information of the first sound mode according to the classified music genre information.

10. The equalizer control system of claim 8, wherein the music genre classifier provides the equalizer controller with information of the first sound mode establishing the equalizer as a flat mode when the status is changed from a music section to a non-music section.

11. The equalizer control system of claim 1, wherein the second sound mode identifier classifies the stored music into the music genre using the highlight extracted from the stored music, identifies the second sound mode for controlling the equalizer, and provides the equalizer controller with information of the second sound mode.

12. The equalizer control system of claim 1, wherein the second sound mode identifier comprises:
a highlight detector to detect the highlight within a predetermined time, the highlight representing the stored music;
a feature extractor to extract a first audio feature, having a value less than a reference value, in a section, and extract a second audio feature, having a value greater than a reference value, in a section, from the highlight; and
a music genre classifier to classify the music into the music genre using the audio feature value.

13. The equalizer control system of claim 1, wherein the equalizer controller comprises:
an equalizer mode establishment unit to establish a frequency response of the equalizer, corresponding to at least one of the first sound mode and the second sound mode;
an equalizer mode selector to select an equalizer mode, corresponding to a sound mode selected from at least one of the first sound mode and the second sound mode; and
a sound reproducer to reproduce sound according to the frequency response, corresponding to the selected equalizer mode.

14. An equalizer control method in a sound player, the method comprising:
classifying a sequential audio stream into one of a category of music and non-music, using an extracted audio feature value;
classifying the music classified sequential audio stream into a music genre;
identifying a sound mode from a plurality of sound modes according to the classified music genre; and
controlling the equalizer corresponding to the identified sound mode.

15. An equalizer control method in a sound player, the method comprising:
extracting a highlight from a stored music clip;
classifying the music clip into a music genre using the extracted highlight;
identifying a sound mode from a plurality of sound modes, according to the classified music genre of the music clip; and
controlling the equalizer corresponding to the identified sound mode.

16. An equalizer control method in a sound player, the method comprising:
classifying a sequential audio stream into one of a category of music and non-music, based on an extracted audio feature value;
identifying a first sound mode of the equalizer from a plurality of sound modes, according to the classified category;
identifying a second sound mode of the equalizer from the plurality of sound modes, by classifying stored music into a music genre using a highlight extracted from the stored music;
establishing in advance an equalizer mode, corresponding to each of the sound modes;
selecting one of the first sound mode and the second sound mode by analyzing the first and second sound modes; and
controlling the equalizer according to the selected sound mode.

17. The equalizer control method in claim 16, wherein the identifying the first sound mode comprises:
segmenting the sequential audio stream into an audio clip of a predetermined time segment;
extracting the audio feature value from the audio clip;
classifying the audio clip into one of a music category or a non-music category using the audio feature value;
recording the music category or the non-music category status; and
classifying the music into the music genre after comparing a present category status with a previous category status, recorded in a status register.

18. The equalizer control method in claim 17, wherein the extracting the audio feature value extracts a first audio feature, having a value less than a reference value, in a section, and a second audio feature, having a value less than a reference value, in a section, from the audio clip.

19. The equalizer control method in claim 17, further comprising:
maintaining a present sound mode when a present category status is the same as a previous category status after comparing the present category status with the previous category status.

20. The equalizer control method in claim 19, wherein the maintaining of the present sound mode maintains the present sound mode without a change from the previous mode, when there is no change in a present audio clip status from one music section to another music section.

21. The equalizer control method in claim 17, wherein the identifying of the first sound mode identifies the first sound mode as a flat mode when a category of the audio clip is the non-music.

22. The equalizer control method in claim 17, further comprising:
reversing a status when a present category status is the same as a previous category status after comparing a present category information with a previous category information, and recording the reversed status in a status register.

23. The equalizer control method in claim 17, further comprising:
classifying the genre of the music when the present audio clip status is changed from a non-music section to a music section after comparing a present category information with a previous category information, and providing the equalizer controller with the classified genre information.

24. The equalizer control method in claim 17, wherein the classifying the genre of the sound source establishes the first sound mode as a flat mode when a present audio clip status is changed from a music section to a non-music section after comparing a present category information with a previous category information.

25. The equalizer control method in claim 16, wherein the identifying the second sound mode comprises:
detecting the highlight, within a predetermined time, the highlight representing the music;
extracting the audio feature value in a section less than a reference value, and extracting the audio feature value in a section greater than the reference value, from the highlight; and
classifying the music into the music genre using the extracted audio feature value.

26. The equalizer control method in claim 16, wherein the controlling the equalizer comprises:
providing a frequency response of the established sound mode;
selecting a frequency response for a sound mode selected from one of the first sound mode and the second sound mode; and
reproducing the sound by controlling the equalizer according to the selected frequency response.

27. At least one medium comprising computer readable code to control at least one processing element to implement a summary clip generation method, the method comprising:
classifying a sequential audio stream into a one of a category of music and non-music based on an extracted audio feature value;
classifying the music classified sequential audio stream into a music genre;
identifying a sound mode from a plurality of sound modes according to the classified genre; and
controlling the equalizer, corresponding to the identified sound mode.

28. An equalizer control method, comprising:
extracting an audio feature from audio data;
classifying the audio data into a music genre based on the extracted audio data; and
controlling the equalizer to determine a sound mode, from a plurality of sound modes, based on the classified music genre.

29. The equalizer control method of claim 28, wherein the extracting comprises extracting a timbre feature value and a rhythm feature value.

30. The equalizer control method of claim 28, wherein the extracting further comprises:
segmenting the audio data into sub-frames;
performing a short term FFT with respect the segmented audio data; and
extracting a spectral feature of the audio data.

31. The equalizer control method of claim 30, wherein the extracted spectral feature comprises at least one of a spectral centroid, a spectral bandwidth, a spectrum roll-off, a spectral flux, and a spectral flatness.

32. The equalizer control method of claim 28, wherein the classifying of the musical genre is accomplished using statistical classification methods.
